(19) United States
(12) Patent Application Publication
(10) Pub. No.: US 2025/0131306 A1
(43) Pub. Date: Apr. 24, 2025

(54) Non-Galvanic and Differential Coupling of Quantum Bit Chips

(71) Applicant: International Business Machines Corporation, Armonk, NY (US)

(72) Inventors: Aaron FINCK, White Plains, NY (US); Joseph Robert SUTTLE, Chappaqua, NY (US)

(21) Appl. No.: 18/492,020

(22) Filed: Oct. 23, 2023

(51) Int. Cl. G06N 10/40; H10N 60/12; H10N 60/80

(52) U.S. Cl. CPC G06N 10/40; H10N 60/12; H10N 60/805

(57) ABSTRACT

A package structure comprises a first quantum bit chip and a second quantum bit chip mounted on a carrier substrate. The carrier substrate comprises an inter-chip coupling network which is configured to provide non-galvanic and differential coupling of the first quantum bit chip and the second quantum bit chip.

### BACKGROUND

This disclosure relates generally to superconducting quantum computing systems and, in particular, techniques for coupling quantum bit chips to construct, e.g., a quantum computer. A quantum computing system can be implemented using superconducting circuit quantum electrodynamics (cQED) architectures that are constructed using quantum circuit components such as, e.g., superconducting quantum bits and other types of superconducting quantum devices that are controlled using microwave and/or flux bias control signals. In general, superconducting quantum bits (qubits) are electronic circuits which are implemented using components such as superconducting tunnel junctions (e.g., Josephson junctions), superconducting quantum interference devices (SQUIDs), inductors, and/or capacitors, etc., and which behave as quantum mechanical anharmonic (non-linear) oscillators with quantized states, when cooled to cryogenic temperatures. A qubit can be effectively operated as a two-level system in a computational subspace comprising a ground state |0 [symbol] and a first excited state |1 [symbol] of the qubit, due to the anharmonicity imparted by a non-linear inductor element (e.g., Josephson junction inductance) of the qubit, which allows the ground and the first excited states to be uniquely addressed at a transition frequency of the qubit, without significantly disturbing higher excited states of the qubit (e.g., |2 [symbol] ), |3 [symbol] etc.).

Various types of quantum information processing algorithms can be implemented using a superconducting quantum processor which comprises multiple superconducting qubits which can be coherently controlled, placed into quantum superposition states, exhibit quantum interference effects, and become entangled with one another, by applying various types of quantum gate operations (e.g., single-qubit gate operations, two-qubit gate operations, etc.) to the superconducting qubits. As quantum processors are scaled with increasing numbers of superconducting qubits and higher integration densities, a primary challenge is being able to scale up the number of qubits without introducing additional channels of noise and unwanted exchange interactions that result in correlated gate errors.

In this regard, techniques for scaling quantum processors include modular approaches in which a plurality of high-yielding quantum bit chips are individually fabricated and packaged together to form larger-scale quantum processors. Such smaller quantum bit chips are easier to fabricate and can be screened for defects before being packaged together. While modular architectures allow larger quantum processor devices to be built from smaller units, it is non-trivial to coupling individual qubit chips together using quantum coherent interconnects and coupling schemes that are sufficiently immune to noise that results of unwanted package modes, wherein such noise can perturb quantum bit states and introduce gate errors when performing two-qubit gate operations between quantum bits that are disposed on different quantum bit chips.

### SUMMARY

Exemplary embodiments of the disclosure include package structures (e.g., multi-qubit chip package structures) which comprise qubit chips that are coupled using non-galvanic and differential coupling components. For example, an exemplary embodiment includes a package structure which comprises a first quantum bit chip and a second quantum bit chip mounted on a carrier substrate. The carrier substrate comprises an inter-chip coupling network disposed on the carrier substrate. The inter-chip coupling network is configured to provide non-galvanic and differential coupling of the first quantum bit chip and the second quantum bit chip.

Advantageously, the differential coupling serves to provide immunity to noise that results from package modes that may exist between separate quantum bit chips mounted on a common carrier substrate (or different carrier substrates). In addition, non-galvanic connections permit the coupling of quantum bit chips without additional bonding steps, giving greater flexibility in assembling modular quantum processors comprising a plurality of individual quantum bit chips which are mounted on a common carrier substrate (or different carrier substrates), and operatively coupled together to implement large arrays of quantum bits.

In another exemplary embodiment, as may be combined with the preceding paragraphs, the inter-chip coupling network comprises a differential coupling capacitor, and a first pair of differential transmission lines connected to the differential coupling capacitor.

In another exemplary embodiment, as may be combined with the preceding paragraphs, the differential coupling capacitor is aligned to superconducting pads of a first quantum bit on the first quantum bit chip to implement a vacuum gap capacitor which provides a non-galvanic connection. The first pair of differential lines are coupled to a tunable coupler on the second quantum bit chip.

In another exemplary embodiment, as may be combined with the preceding paragraphs, the inter-chip coupling network further comprises a second pair of differential transmission lines which are connected to the differential coupling capacitor and coupled to a second quantum bit on the second quantum bit chip.

Another exemplary embodiment includes a package structure which comprises a first quantum bit chip and a second quantum bit chip, which are mounted on a carrier substrate. The first quantum bit chip comprises a first quantum bit. The second quantum bit chip comprises a second quantum bit, and a tunable coupler that is configured to control exchange interactions between the first quantum bit and the second quantum bit. The carrier substrate comprises an inter-chip coupling network which is configured to provide non-galvanic and differential coupling of the tunable coupler and the first quantum bit chip.

Another exemplary embodiment includes a package structure which comprises a first quantum bit chip and a second quantum bit chip. The first quantum bit chip is mounted on a first carrier substrate. The second quantum bit chip is mounted on a second carrier substrate, wherein an extended portion of the second quantum bit chip extends past an edge of the second carrier substrate and overlaps a region of the first carrier substrate. An inter-chip coupling network is disposed at least in part in the overlapped region of the first carrier substrate, and configured to provide non-galvanic and differential coupling of the first quantum bit chip and the second quantum bit chip.

Other embodiments will be described in the following detailed description of exemplary embodiments, which is to be read in conjunction with the accompanying figures.

### BRIEF DESCRIPTION OF THE DRAWINGS

FIG. 1 schematically illustrates a package structure comprising qubit chips that are coupled using non-galvanic and differential coupling components, according to an exemplary embodiment of the disclosure.

FIG. 2A schematically illustrates an exemplary superconducting qubit which can be implemented on a qubit chip of the package structure of FIG. 1, according to an exemplary embodiment of the disclosure.

FIG. 2B schematically illustrates an exemplary tunable coupler which can be implemented on a qubit chip of the package structure of FIG. 1, according to an exemplary embodiment of the disclosure.

FIG. 3 is a schematic perspective view of a package structure comprising qubit chips that are coupled using non-galvanic and differential coupling components, according to an exemplary embodiment of the disclosure.

FIG. 4 is a schematic perspective view of a package structure comprising qubit chips that are coupled using non-galvanic and differential coupling components, according to another exemplary embodiment of the disclosure.

FIG. 5 is a schematic perspective view of a package structure comprising qubit chips that are coupled using non-galvanic and differential coupling components, according to another exemplary embodiment of the disclosure.

FIG. 6A schematically illustrates modes of excitation of a tunable coupler having a flux-tunable multimode qubit architecture, according to an exemplary embodiment of the disclosure.

FIG. 6B illustrates a schematic lumped-element circuit representation of a tunable coupler comprising a flux-tunable multimode qubit architecture, according to an exemplary embodiment of the disclosure.

FIG. 7 is a schematic perspective view of a package structure comprising qubit chips that are coupled using non-galvanic and differential coupling components, according to another exemplary embodiment of the disclosure.

FIG. 8 is a schematic cross-sectional side view of a package structure comprising qubit chips that are coupled using non-galvanic and differential coupling components, according to another exemplary embodiment of the disclosure.

FIG. 9 illustrates a flow diagram of a process for fabricating a package structure comprising qubit chips that are coupled using non-galvanic and differential coupling components, according to an exemplary embodiment of the disclosure.

FIG. 10 schematically illustrates a quantum computing system which comprises a quantum process that is implemented using a multi-qubit chip package structure, according to an exemplary embodiment of the disclosure.

### DETAILED DESCRIPTION

Exemplary embodiments of the disclosure will now be described in further detail with regard to techniques for packaging multiple qubit chips to construct large scale quantum processors and, in particular, techniques for coupling qubits that are fabricated on different qubit chips. In general, the exemplary coupling techniques as discussed herein enable non-galvanic and differential coupling between qubit chips to facilitate the construction of a high performance, scalable modular architecture where multiple qubit chips are packaged together to construct a quantum processor wherein the chip-to-chip coupling and qubit-qubit coupling is robust against unwanted noise that results from interactions of package modes that may exist between adjacent qubit chips.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs.

Further, it is to be understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise quantum circuit elements (e.g., quantum bits, SQUIDS, tunable couplers, etc.), discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

In addition, the term “quantum bit chip” or “qubit chip” as used herein refers to a die (e.g., semiconductor die) which comprises a superconducting electronic integrated circuit comprising various superconducting components such as qubits, tunable couplers, ground planes, signal coplanar waveguides, and resonators, etc. A plurality of dies having the same and/or different configurations of superconducting electronic integrated circuits, can be fabricated on a wafer (e.g., semiconductor wafer), wherein the individual dies can be diced (cut) from the wafer using a die singulation process to provide singulated dies which can be packaged together to construct a modular quantum processor architecture. The terms “quantum bit chip” and “qubit chip” and “die” are synonymous terms and used interchangeably herein. Moreover, the terms “non-galvanic coupling” or “non-galvanic connection” as used herein refer to non-direct electrical connections, e.g., a connection that is achieved via capacitive coupling, inductive coupling, optical coupling, combinations thereof, etc.

As noted above, for large-scale quantum computation, a quantum processor comprising an array of superconducting qubits can utilize tunable couplers to dynamically control intra-chip qubit-qubit interactions to, e.g., enable high-fidelity two-qubit gate operations (e.g., entanglement operations). On the other hand, a primary challenge in developing a modular quantum processor architecture involves the implementation of high-fidelity, low-latency quantum inter-chip coupling between adjacent qubit chips and in particular, enabling controlled coupling between qubits that are fabricated on different qubit chips to provide high-fidelity two-qubit gate operations between qubits disposed on separate qubit chips. Exemplary embodiments of the disclosure implement tunable couplers with non-galvanic and differential coupling components to implement inter-chip coupling of separate qubit chips, and to mediate interactions between qubits disposed on separate qubit chips.

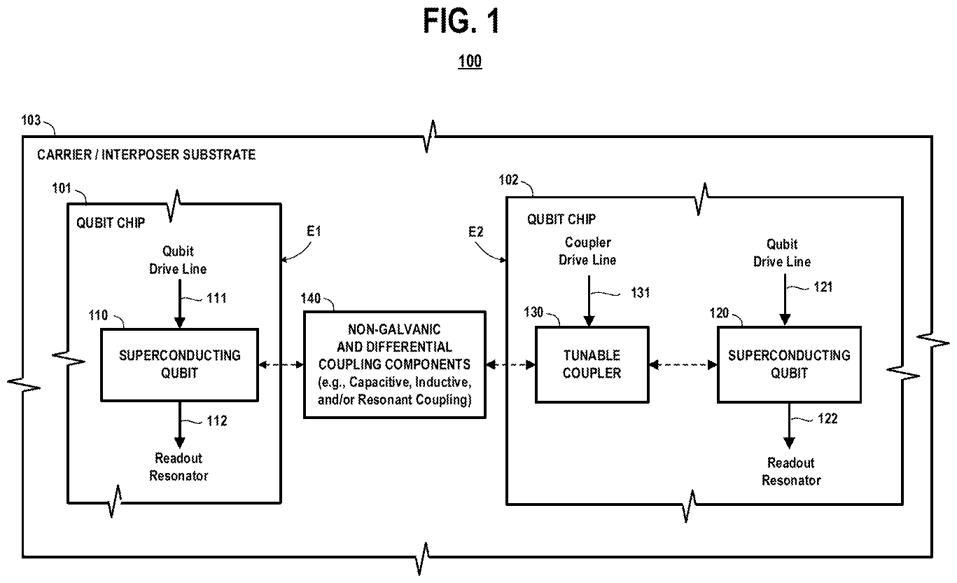

For example, FIG. 1 schematically illustrates a package structure comprising qubit chips that are coupled using non-galvanic and differential coupling components, according to an exemplary embodiment of the disclosure. In particular, FIG. 1 schematically illustrates a package structure 100 comprising a first qubit chip 101, a second qubit chip 102, and a carrier substrate 103 (or interposer). The first and second qubit chips 101 and 102 are flip-chip bonded to the carrier substrate 103 using solder bumps (e.g., indium solder bumps), with a small spacing between respective edges E1 and E2 of the first and second qubit chips 101 and 102. The first qubit chip 101 comprises a first superconducting qubit 110 (or first qubit 110) which is disposed in proximity to the edge E1 of the first qubit chip 101. The second qubit chip 102 comprises a second superconducting qubit 120 (or second qubit 120), and a superconducting tunable coupler 130 (or tunable coupler 130), which are disposed in proximity to the edge E2 of the second qubit chip 102.

The carrier substrate 103 comprises an inter-chip coupling network comprising coupling components 140 that enable, e.g., non-galvanic and differential coupling of the first and second qubit chips 101 and 102. For example, in some embodiments, the coupling components 140 comprise air gap capacitors and one or more differential lines, which are formed on the carrier substrate 103 to provide non-galvanic and differential coupling (e.g., capacitive coupling) of the first and second qubit chips 101 and 102. More specifically, in some embodiments, the coupling components 140 comprise air gap capacitors and differential lines that are configured to couple the tunable coupler 130 to the first qubit 110, the details of which will be explained in further detail below. In addition to capacitive coupling, non-galvanic and differential coupling between the first and second qubit chips 101 and 102 can be implemented through inductive coupling, resonant coupling, and any combination of capacitive, inductive, and/or resonant coupling. For example, inductive coupling can be implemented using a pair of wires leading to an inductor loop, and through pairs of co-planar waveguide resonators which could give resonant enhancement of coupling near the mode frequencies of the resonators. While not specifically shown in FIG. 1, in some embodiments, the carrier substrate 103 comprises other circuit components as desired for a given package structure and given application, such as components to provide microwave shielding, circuitry to interface with qubits and tunable couplers on the individual qubit chips, signal routing for package input/output, ground planes, etc.

Furthermore, as schematically shown in FIG. 1, the package structure 100 comprises a plurality of control lines including, but not limited to, qubit drive lines 111 and 121, and a coupler drive line 131 (e.g., flux bias control line), and qubit readout lines 112 and 122 (e.g., readout resonators). In some embodiments, the qubit drive lines 111 and 121 are coupled (e.g., capacitively coupled via capacitors) to the first and second qubits 110 and 120, respectively. In some embodiments, the qubit drive lines 111 and 121 are configured to apply control signals (e.g., microwave pulse signals) to independently change the states of the respective first and second qubits 110 and 120 (e.g., single-qubit gate operations). In particular, the qubit drive lines 111 and 121 are utilized to, e.g., apply microwave control signals to drive single-qubit X-rotation gates and single-qubit Y-rotation gates, and perform other functions as discussed herein. As is known in the art, the state of a qubit can be changed by applying a microwave control signal (e.g., control pulse) with a center frequency equal to a transition frequency (generally denoted f₀₁) of the qubit, wherein the transition frequency f₀₁ corresponds to an energy difference between the ground state |0 [symbol] and excited state |1 [symbol] of the qubit. In addition, the axis of rotation about a given axis of the Bloch sphere (e.g., X-axis and/or Y-axis) and the amount (angle) of such rotation are based, respectively, on the phase of the microwave control signal, and the amplitude and duration of the microwave control signal.

The coupler drive line 131 is coupled to the tunable coupler 130 and is configured to apply a control signal to tune the frequency of the tunable coupler 130. The coupler drive line 131 can be capacitively coupled or mutually coupled to the tunable coupler, depending on the circuit configuration of the tunable coupler 130. The tunable coupler 130 is configured to mediate the interactions between the first and second qubits 110 and 120, for different types of gate operations. The first and second qubits 110 and 120 and the tunable coupler 130 are coupled through exchange-type interactions. The interaction strength of the first and second qubits 110 and 120 depends on the frequency of the tunable coupler 130, wherein coupler-mediated two-qubit gate operations are implemented by dynamically tuning the frequency of the tunable coupler 130 to achieve a desired interaction between the first and second qubits 110 and 120.

For example, assume that the first and second qubits 110 and 120 have respective transition frequencies of f_{q1} and f_{q2} that are detuned by an amount Δ₁₂=f_{q2}−f_{q1}. The tunable coupler 130 can be dynamically tuned (via a coupler control signal applied on the coupler drive line 131) to operate in a first state (e.g., “OFF” state or “deactivated” state) or a second state (e.g., “ON” state or “activated” state) by changing a frequency (generally denoted as f_{Coupler}) of the tunable coupler 130 between a first (OFF) frequency (denoted f_{C-OFF}), and a second (ON) frequency (denoted f_{C-ON}). The qubit transition frequencies f_{q1} and f_{q2} are detuned from the coupler frequency f_{C-ON} by respective amounts denoted as Δ_{1C} and Δ_{2C}.

In the “OFF” state, the tunable coupler 130 essentially serves to decouple the first and second qubits 110 and 120 by suppressing exchange interaction (static or otherwise) between the first and second qubits 110 and 120. In some embodiments, as explained in further detail below, the tunable coupler 130 comprises a flux-tunable coupler that is maintained in an OFF state by applying a DC flux bias signal (DC current) on the coupler drive line 131. The suppressed residual longitudinal coupling (e.g., suppressed static ZZ interaction) between modes of the first and second qubits 110 and 120 is due to a relatively large detuning between the off frequency f_{C-OFF} of the tunable coupler 130 and the operating frequencies (e.g., transition frequencies of f_{q1} and f_{q2}) of the first and second qubits 110 and 120. In other words, the detuning between the tunable coupler 130 and the first and second qubits 110 and 120 serves to significantly suppress any direct longitudinal coupling between the first and second qubits 110 and 120 and, thus, the state of one qubit will not affect the transition frequency of the other qubit. In this regard, when the tunable coupler 130 is in the OFF state, the first and second qubits 110 and 120 are essentially decoupled with substantially no quantum cross-talk between first and second qubits 110 and 120. This allows single-qubit gate operations to be independently performed on the first and second qubits 110 and 120 without the inducement of coherent errors during such single-qubit gate operations that may otherwise result from the ZZ interaction or direct exchange interactions between the first and second qubits 110 and 120.

On the other hand, the “ON” state of the tunable coupler 130 enables the first and second qubits 110 and 120 to be exchange coupled with the tunable coupler 130 which, in turn, enables/facilitates exchange coupling (e.g., ZZ interaction) between the first and second qubits 110 and 120, which are capacitively coupled to the tunable coupler 130. In some embodiments, as explained in further detail below, the tunable coupler 130 is placed into an ON state by applying a pulse flux bias signal (on top of the DC flux bias signal) to the tunable coupler 130 to enable a controlled amount of exchange interaction (entanglement) between the states of the first and second qubits 110 and 120. In this manner, the tunable coupler 130 is configured to facilitate two-qubit entanglement gates including, but not limited to longitudinal two-qubit gates (e.g., a controlled-phase gate (referred to as CPHASE gate or CZ gate)) and transversal two-qubit gates (e.g., SWAP or iSWAP gates).

To perform an entanglement gate operation, the tunable coupler 130 can be driven to the ON frequency f_{C-ON} which is near, e.g., a transition frequency or resonant frequency, of the tunable coupler 130, which causes a relatively large amount of longitudinal coupling (ZZ coupling) between the tunable coupler 130 and the first and second qubits 110 and 120 due to higher energy excitations in the first and second qubits 110 and 120 and tunable coupler 130, which are at similar energies. The longitudinal coupling between the tunable coupler 130 and the first and second qubits 110 and 120 causes a state-dependent AC-Stark shifting of the transition frequencies of the first and second qubits 110 and 120, wherein the Stark shifting of the frequency of a given qubit is a function of, e.g., (i) a coupling strength between the tunable coupler 130 and the given qubit, and (ii) an amount of detuning between the operating frequency of the coupler circuitry the operating frequency given qubit. In certain instances, the coupler-mediated ZZ interaction provides a way to entangle two different qubits and create, e.g., a CPHASE gate, because a state-dependent shift in qubit frequency can be made equivalent to a state-dependent phase-shift. ZZ interactions are sometimes referred to as longitudinal coupling or denoted as chi or 2-chi coupling.

Further, in some embodiments, the qubit readout lines 112 and 122 are coupled to the first and second qubits 110 and 120, respectively, using known techniques. In some embodiments, the qubit readout lines 112 and 122 comprise transmission line readout resonators (e.g., half-wavelength coplanar waveguide resonators) which are configured to have resonant frequencies that are detuned from the respective transition frequencies of the respective first and second qubits 110 and 120. In some embodiments, the first and second qubits 110 and 120 are dispersively coupled to the qubit readout lines 112 and 122 for their state readout. In some embodiments, a dispersive readout operation for reading the quantum state of a given superconducting qubit which is coupled to a given readout resonator, is performed by applying a radio frequency (RF) readout control signal to the given readout resonator, and detecting/processing the readout signal that is reflected out from the given readout resonator. An RF readout control signal that is applied to the given readout resonator has a single frequency tone that is the same or similar to the resonant frequency of the readout resonator, a pulse envelope with a given pulse shape (e.g., gaussian pulse envelope), and given pulse duration. In the dispersive regime of qubit-resonator coupling, the RF readout control signal interacts with the given qubit/resonator system, and the resulting output readout signal which is reflected out from the given readout resonator comprises information (e.g., phase and/or amplitude) that is qubit-state dependent.

In some embodiments, as schematically illustrated in FIG. 1, the qubit drive lines 111 and 121, the coupler drive line 131, and/or the qubit readout lines 112 and 122 are formed at least in part on the respective qubit chips 101 and 102. In other embodiments, the qubit drive lines 111 and 121, the coupler drive line 131, and/or the qubit readout lines 112 and 122 are formed at least in part on the carrier substrate 103 and capacitively and/or magnetically coupled to the respective first and second qubits 110 and 120 on the first and second qubit chips 101 and 102.

While FIG. 1 schematically illustrates a single inter-chip qubit-coupler-qubit quantum system between the first and second qubit chips 101 and 102 for ease of illustration and explanation, it is to be understood that the first and second qubit chips 101 and 102 can have multiple inter-chip qubit-coupler-qubit quantum systems disposed at the edges E1 and E2 of the first and second qubit chips 101 and 102, and that the carrier substrate 103 can have multiple instances of the coupling components 140 to enable inter-chip coupling of multiple qubit-coupler-qubit quantum systems. Moreover, while FIG. 1 schematically illustrates each of the first and second qubit chips 101 and 102 having a single qubit (e.g., the first and second qubit 110 and 120), it is to be understood that the first and second qubit chips 101 and 102 can each have a respective qubit array comprising multiple qubits with adjacent qubits coupled together (intra-chip coupling) using tunable couplers. In this regard, one or more qubits of a first qubit array on the first qubit chip 101 (which are disposed in proximity to the edge E1 of the first qubit chip 101) can be inter-chip coupled to one or more corresponding qubits of a second qubit array on the second qubit chip 102 (which are disposed in proximity to the edge E2 of the second qubit chip 102) using inter-chip coupling components and techniques as discussed herein.

Moreover, while the first and second qubits 110 and 120 are generically illustrated in FIG. 1, it is to be understood that the first and second qubits 110 and 120 can be implemented using any type of superconducting qubit architecture. For example, the first and second qubits 110 and 120 can be implemented using superconducting transmon qubits, fluxonium qubits, multimode qubits (e.g., two-junction qubits, or tunable coupling qubits), and other suitable types of superconducting qubits. The first and second qubits 110 and 120 can be fixed-frequency qubits, or tunable frequency qubits. Moreover, in some embodiments, embodiments, the tunable coupler 130 is implemented using a frequency tunable qubit, which operates as a bus coupler but does not encode quantum information.

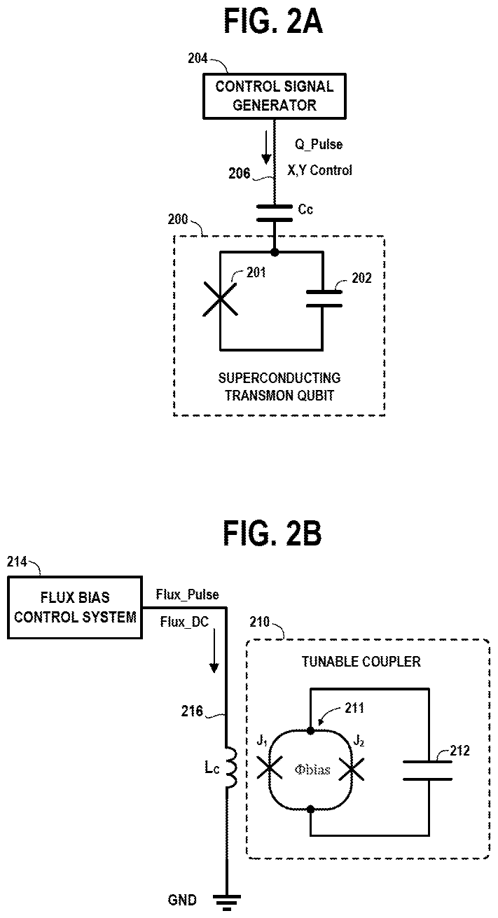

FIG. 2A schematically illustrates an exemplary superconducting qubit which can be implemented on a qubit chip of the package structure of FIG. 1, according to an exemplary embodiment of the disclosure. In particular, FIG. 2A schematically illustrates a superconducting qubit 200 which comprises a fixed frequency transmon qubit that comprises a superconducting Josephson junction 201 connected in parallel with a capacitor 202. The Josephson junction 201 functions as a non-linear inductor which, when shunted with the capacitor 202, forms an anharmonic LC oscillator with individually addressable energy levels (e.g., two lowest energy levels corresponding to computational basis states including the ground state |0 [symbol] and the first excited state |1 [symbol] ). In some embodiments, the first and second qubits 110 and 120 in FIG. 1 can be implement using the superconducting qubit 200 of FIG. 2A (e.g., fixed-frequency transmon qubit), or other types of superconducting qubits such as fluxonium qubits, etc.

As further shown in FIG. 2A, a control signal generator 204 is configured to generate a given microwave pulse (denoted Q_Pulse) to drive single qubit X- and Y-rotation gates on the superconducting qubit 200. The microwave pulse, Q_Pulse, is applied to a qubit drive line 206 which is capacitively coupled to the superconducting qubit 200 via a coupling capacitor Cc. In some embodiments, the control signal generator 204 comprises a multi-channel arbitrary waveform generator (AWG) which is configured to generate control signals to control the operation (e.g., state change and readout) of superconducting qubit 200. To implement an X gate and/or Y gates, a suitable microwave control pulse Q_Pulse is generated which has a center frequency (tone) near or equal to the transition frequency of the superconducting qubit 200, and suitably shaped pulse envelope (e.g., a gaussian pulse envelope), that is calibrated to drive f₀₁ transitions of the superconducting qubit 200, while suppressing f₁₂ and higher transitions. The microwave control pulse Q_Pulse is configured to change the state of the superconducting qubit 200 by rotating the state of the given qubit about an axis of the Bloch sphere, wherein such rotations include X-axis rotations, Y-axis rotations, and/or rotations about any axis in the X-Y plane of the Bloch sphere, wherein the axis of rotation about a given axis of the Bloch sphere and the amount (angle) of such rotation are based, respectively, on the phase of the microwave control signal, and the amplitude and duration of the microwave control signal.

In addition, the control signal generator 204 is configured to generate readout control signal which comprises an RF control pulse with a center frequency that corresponds to the resonant frequency of a readout resonator that is coupled to the superconducting qubit 200. As noted above, a readout resonator that is coupled to a given qubit comprises, e.g., half-wavelength coplanar waveguide resonator, which is utilized to readout the quantum state of the given qubit using, e.g., dispersive readout systems and techniques, which are well-known to those of ordinary skill in the art. For ease of illustration, FIG. 2A does not illustrate the readout resonator or readout signal chain which transmits the readout signal to readout processing circuitry.

Next, FIG. 2B schematically illustrates an exemplary tunable coupler which can be implemented on a qubit chip of the package structure of FIG. 1, according to an exemplary embodiment of the disclosure. In particular, FIG. 2B schematically illustrates a tunable coupler 210 which comprises a flux-tunable transmon qubit coupler having a flux-tunable operating frequency. The tunable coupler 210 is similar in structure to the superconducting qubit 200 of FIG. 2A, except that the transmon qubit coupler is configured to be flux-tunable by implementing DC SQUID 211 in place of the single Josephson junction 201. The DC SQUID 211 comprises a first Josephson junction J1 and a second Josephson junction J2, which are connected in parallel to form a superconducting loop (referred to as SQUID loop) through which an external magnetic flux bias Φ_{Bias} is threaded to adjust the frequency of the tunable coupler 210 to control the interaction (e.g., facilitate exchange interaction or suppress crosstalk) between adjacent qubits.

As further shown in FIG. 2B, a flux bias control system 214 is configured to generate flux bias control signals, denoted Flux_DC and Flux_Pulse, to tune the operating frequency of the tunable coupler 210. The flux bias control signals Flux_DC and Flux_Pulse is applied to a coupler drive line 216, and magnetically coupled to the DC SQUID 211 via a coupling inductor Lc. The Flux_DC control signal comprises a DC flux bias signal that is magnetically coupled to the DC SQUID 211 to generate a static magnetic field that threads through the superconducting loop of the DC SQUID 211. The static magnetic field modulates the critical current, and thus, the Josephson energy of the DC SQUID 211 in a manner which causes the tunable coupler 210 to be maintained in an OFF state which, as noted above, suppresses exchange interactions between adjacent superconducting qubits.

On the other hand, a flux bias control signal (Flux_Pulse) can be generated to temporarily place the tunable coupler 210 into an ON state, when needed, to modulate an exchange interaction between the first and second superconducting qubits. In this instance, the flux bias control signal (Flux_Pulse) is combined with the DC flux bias signal (Flux_DC) to dynamically increase the flux bias current through the coupling inductor Lc and thereby change the magnetic of the flux bias Φ_{Bias} that is threaded through the superconducting loop of the DC SQUID 211 for purposes of, e.g., placing the tunable coupler 210 into an ON state for a duration of the flux bias control signal (Flux_Pulse) to facilitate a coupler-mediated entanglement gate between a first and second qubit.

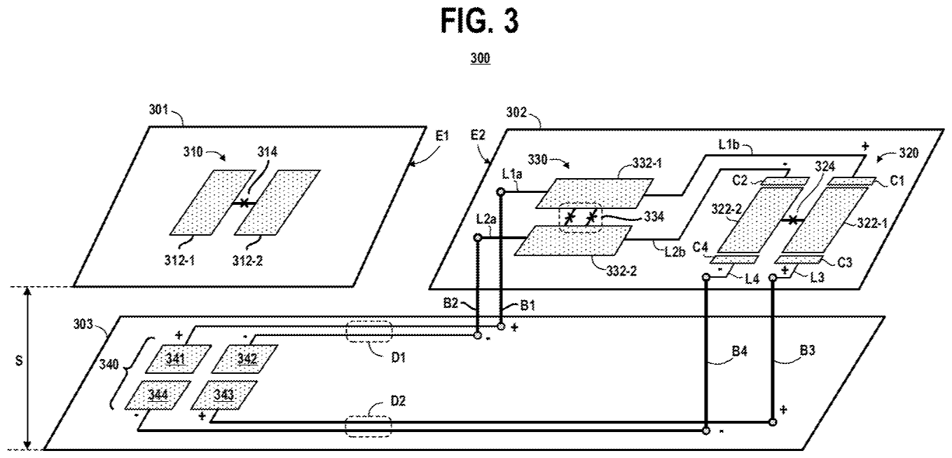

The package structure 100 of FIG. 1 can be implemented using various architectures and implementations of superconducting qubits, tunable couplers, and inter-chip coupling components. For example, FIG. 3 is a schematic perspective view of a package structure comprising qubit chips that are coupled using non-galvanic and differential coupling components, according to an exemplary embodiment of the disclosure. In particular, FIG. 3 schematically illustrates a package structure 300 comprising a first qubit chip 301, a second qubit chip 302, and a carrier substrate 303 (or interposer). The first and second qubit chips 301 and 302 have frontside surfaces with patterned metallization and circuitry which defines qubits, tunable couplers, transmission lines, etc. The first and second qubit chips 301 and 302 are flip-chip bonded via solder bump connections to a frontside surface of the carrier substrate 303, such that the first and second qubit chips 301 and 302 are (i) horizontally separated by a small gap between respective edges E1 and E2 of the first and second qubit chips 301 and 302, and (ii) vertically separated from the carrier substrate 303 by a vertical spacing S that defines a vacuum gap between the frontside surface of the carrier substrate 303 and the frontside surfaces of the first and second qubit chips 301 and 302. The vertical spacing S is fixed by the height of the bump connections post-bonding, wherein the vertical spacing S can be in a range of, e.g., 1 micron to 5 microns.

For example, FIG. 3 shows bump connections B1, B2, B3, and B4 (e.g., indium solder bump connections) between the second qubit chip 302 and the carrier substrate 303. However, for ease of illustration, FIG. 3 does not show ground planes on the first and second qubit chips 301 and 302 or the carrier substrate 303, or bump connections that would be used for, e.g., bonding the ground planes of the frontside surfaces of the first and second qubit chips 301 and 302 to the ground planes on the frontside surface of the carrier substrate 303, or used for making other direct (galvanic) connections between the carrier substrate 303 and other components on the first and second qubit chips 301 and 302.

The first qubit chip 301 comprises a first transmon qubit 310 which is formed on the frontside surface of the first qubit chip 301 and disposed in proximity to the edge E1 of the first qubit chip 301. In particular, FIG. 3 schematically shows an exemplary planar circuit configuration of the first transmon qubit 310 which comprises a first superconducting pad 312-1, a second superconducting pad 312-2, and a Josephson junction 314 that is coupled to, and disposed between, the first and second superconducting pads 312-1 and 312-2. The first and second superconducting pads 312-1 and 312-2 comprise first and second electrodes of a coplanar parallel-plate capacitor of the first transmon qubit 310, which is coupled in parallel with the Josephson junction 314.

The second qubit chip 302 comprises a second transmon qubit 320, and a tunable coupler 330, which are formed on the frontside surface of the second qubit chip 302 in proximity to the edge E2 of the second qubit chip 302. The second transmon qubit 320 comprises a first superconducting pad 322-1 and a second superconducting pad 322-2 (which form a parallel plate capacitor), and a Josephson junction 324 that is coupled to, and between, the first and second superconducting pads 322-1 and 322-2. Further, the tunable coupler 330 comprises a tunable transmon qubit coupler (similar to the tunable coupler 210, FIG. 2B), wherein the tunable coupler 330 comprises a first superconducting pad 332-1 and a second superconducting pad 332-2 (which form a parallel plate capacitor), and a SQUID 334 comprising two Josephson junctions that are coupled to, and disposed between, the first and second superconducting pads 332-1 and 332-2.

The carrier substrate 303 comprises a differential coupling capacitor 340, a first pair of differential lines D1, and a second pair of differential lines D2, which are formed on the frontside surface of the carrier substrate 303. The differential coupling capacitor 340 comprises a plurality of capacitor pads 341, 342, 343, and 344. As schematically illustrated in FIG. 3, the first superconducting pad 312-1 of the first transmon qubit 310 is disposed over and aligned to the capacitor pads 341 and 344, while the second superconducting pad 312-2 of the first transmon qubit 310 is disposed over and aligned to the capacitor pads 342 and 343. In this configuration, the differential coupling capacitor 340 and the first and second superconducting pads 312-1 and 312-2 of the first transmon qubit 310 are configured to implement a vacuum gap capacitor structure which provides a non-galvanic connection between the first transmon qubit 310 (on the first qubit chip 301) and the carrier substrate 303.

The exemplary package structure 300 comprises a qubit-coupler-qubit system in which the tunable coupler 330 is capacitively coupled to both the first transmon qubit 310 and the second transmon qubit 320. In particular, the tunable coupler 330 is coupled to the first transmon qubit 310 using a first differential coupling network which comprises first and second transmission lines L1a and L2a on the second qubit chip 302, the first and second bump connections B1 and B2, the first pair of differential lines D1, and the capacitor pads 341 and 342. In this configuration, the first superconducting pad 332-1 of the tunable coupler 330 is connected to the capacitor pad 341 via a series connection of the transmission line L1a, the first bump connection B1, and one transmission line of the pair of differential lines D1, while the second superconducting pad 332-2 of the tunable coupler 330 is connected to the capacitor pad 342 by a series connection of the transmission line L2a, the second bump connection B2, and the other transmission line of the pair of differential lines D1.

In addition, the tunable coupler 330 is capacitively coupled to the second transmon qubit 320 by a second differential coupling network which comprises first and second transmission lines L1b and L2b on the second qubit chip 302, and first and second capacitor pads C1 and C2. In particular, the first capacitor pad C1 is connected to the first superconducting pad 332-1 of the tunable coupler 330 via the transmission line L1b, while the second capacitor pad C2 is connected to the second superconducting pad 332-2 of the tunable coupler 330 via the transmission line L2b. The first capacitor pad C1 is disposed adjacent to an edge of the first superconducting pad 322-1 of the second transmon qubit 320 to implement a coplanar parallel plate capacitor with a given coupling capacitance. Similarly, the second capacitor pad C2 is disposed adjacent to an edge of the second superconducting pad 322-2 of the second transmon qubit 320 to implement a coplanar parallel plate capacitor with a given coupling capacitance.

Further, the second transmon qubit 320 is capacitively coupled to the differential coupling capacitor 340 by a third differential coupling network which comprises third and fourth capacitor pads C3 and C4 on the second qubit chip 302, third and fourth transmission lines L3 and L4 on the second qubit chip 302, the bump connections B3 and B4, and the second pair of differential lines D2 on the carrier substrate 303. In this configuration, the third capacitor pad C3 is connected to the capacitor pad 343 of the differential coupling capacitor 340 by a series connection of the third transmission line L3, the third bump connection B3, and one transmission line of the second pair of differential lines D2, while the fourth capacitor pad C4 is connected to the capacitor pad 344 of the differential coupling capacitor 340 by a series connection of the fourth transmission line L4, the fourth bump connection B4, and the other transmission line of the second pair of differential lines D2. The third capacitor pad C3 is disposed adjacent to an edge of the first superconducting pad 322-1 of the second transmon qubit 320 to implement a coplanar parallel plate capacitor with a given coupling capacitance. Similarly, the fourth capacitor pad C3 is disposed adjacent to an edge of the second superconducting pad 322-2 of the second transmon qubit 320 to implement a coplanar parallel plate capacitor with a given coupling capacitance.

It is to be appreciated that the differential coupling framework of the package structure 300 serves to reduce or eliminate any adverse effects of external fields or other sources of noise. For example, with the exemplary package structure 300, the gap between the edges E1 and E2 of the first and second qubit chips 301 and 302 can have package modes (e.g., long range modes) that can add noise into the transmission lines, e.g., the noise from the interactions of the package modes typically interacts with a common mode of exposed transmission lines. However, the differential coupling network configuration provides good immunity to such package modes and serves to significantly reduce or otherwise eliminate the coupling of package mode noise to the first and second transmon qubits 310 and 320.

Furthermore, the differential coupling framework of the package structure 300 serves to significantly reduce or otherwise eliminate static or residual exchange coupling (e.g., ZZ coupling) between the first and second transmon qubits 310 and 320 when the tunable coupler 330 is in an OFF state. For example, the first and second pairs of differential lines D1 and D2 are configured to provide exchange couplings between the first and second transmon qubits 310 and 320, but with different signs (polarities), e.g., plus (+) and minus (−) signs, as shown in FIG. 3. In particular, as shown in FIG. 3, at any given time, the capacitor pads 341 and 344 of the differential coupling capacitor 340 (which are aligned to the first superconducting pad 312-1 of the first transmon qubit 310) have opposing polarities, and the capacitor pads 342 and 344 of the differential coupling capacitor 340 (which are aligned to the second superconducting pad 312-2 of the first transmon qubit 310) have opposing polarities. With this differential capacitive coupling configuration, when tunable coupler 330 is tuned to be in an OFF state, the two different couplings can be cancelled, leading to zero net exchange coupling between the first and second transmon qubits 310 and 320.

More specifically, even when the tunable coupler 330 is tuned to be in an OFF state, there will still be some small amount of exchange coupling between the first and second transmon qubits 310 and 320 through a first differential path that includes the tunable coupler 330, the first pair of differential lines D1, and the differential coupling capacitor 340. However, due to the differential capacitive coupling between the first and second transmon qubits 310 and 320 through a second differential path that includes the second pair of differential lines D2 and the differential coupling capacitor 340, there will be some small amount of exchange coupling between the first and second transmon qubits 310 and 320 through the second differential path. However, the exchange couplings between the first and second transmon qubits 310 and 320 through the first and second differential paths effectively cancel each other, leading to zero net exchange coupling between the first and second transmon qubits 310 and 320.

In this instance, the magnitudes of the opposite charges on the capacitor pads 341 and 344 of the differential coupling capacitor 340 will be the same or substantially the same, thereby providing a net zero charge on the capacitor pads 341 and 344 which are aligned and capacitively coupled to the first superconducting pad 312-1 of the first transmon qubit 310. Similarly, the magnitudes of the opposite charges on the capacitor pads 342 and 343 of the differential coupling capacitor 340 will be the same or substantially the same, thereby providing a net zero charge on the capacitor pads 342 and 343 which are aligned and capacitively coupled to the second superconducting pad 312-2 of the first transmon qubit 310. On the other hand, when the tunable coupler 330 is tuned to be in an ON state, the magnitude of the exchange coupling between the first and second transmon qubits 310 and 320 through the first differential path (which includes the tunable coupler 330, the first pair of differential lines D1, and the differential coupling capacitor 340) will be greater than the magnitude of the exchange coupling between the first and second transmon qubits 310 and 320 through the second differential path (which includes the second pair of differential lines D2 and differential coupling capacitor 340), resulting in a net exchange coupling between the first and second transmon qubits 310 and 320 to enable, e.g., a controlled-phase entangling gate.

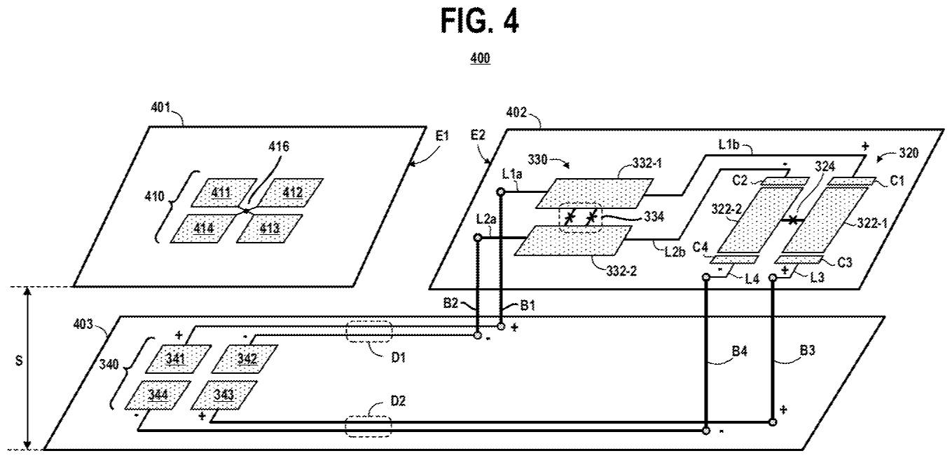

Next, FIG. 4 is a schematic perspective view of a package structure comprising qubit chips that are coupled using non-galvanic and differential coupling components, according to another exemplary embodiment of the disclosure. In particular, FIG. 4 schematically illustrates a package structure 400 comprising a first qubit chip 401, a second qubit chip 402, and a carrier substrate 403 (or interposer), wherein the first and second qubit chips 401 and 402 are flip-chip bonded to the carrier substrate 403 using bump connections (e.g., bump connections B1, B2, B3, B4). In the exemplary embodiment, the second qubit chip 402 and the carrier substrate 403 have the same circuit architecture as the second qubit chip 302 and the carrier substrate 303 of FIG. 3, the details of which will not be repeated. However, FIG. 4 illustrates an exemplary embodiment in which the first qubit chip 401 comprises a superconducting quadrupole transmon qubit 410.

The superconducting quadrupole transmon qubit 410 comprises a plurality of superconducting pads 411, 412, 413, and 414, and a Josephson junction 416 having a Manhattan Josephson junction framework. The superconducting quadrupole transmon qubit 410 operates in a similar manner to, e.g., the first transmon qubit 310 (FIG. 3) with a Josephson junction coupled in parallel with a capacitor, except that the first and second capacitor electrodes of the superconducting quadrupole transmon qubit 410 are arranged in a rectangular array and have a quadrupole charge pattern when excited. In particular, the superconducting pads 411 and 413 are configured to implement a first capacitor electrode of the capacitor, and are commonly connected to a first electrode of the Josephson junction 416. The superconducting pads 412 and 414 are configured to implement a second capacitor electrode of the capacitor, and are commonly connected to a second electrode of the Josephson junction 416.

As schematically illustrated in FIG. 4, the superconducting pads 411, 412, 413, and 414 of the superconducting quadrupole transmon qubit 410 are disposed over and aligned to the capacitor pads 341, 342, 343, and 344, respectively, of the differential coupling capacitor 340. In this regard, the differential coupling capacitor 340 and the superconducting pads 411, 412, 413, and 414 of the superconducting quadrupole transmon qubit 410 are configured to implement a vacuum gap capacitor structure which provides a non-galvanic connection between the superconducting quadrupole transmon qubit 410 (on the first qubit chip 401) and the carrier substrate 403. The structural configuration of the superconducting quadrupole transmon qubit 410 serves to further reduce coupling to stray fields or modes that might exist between the first and second qubit chips 401 and 402.

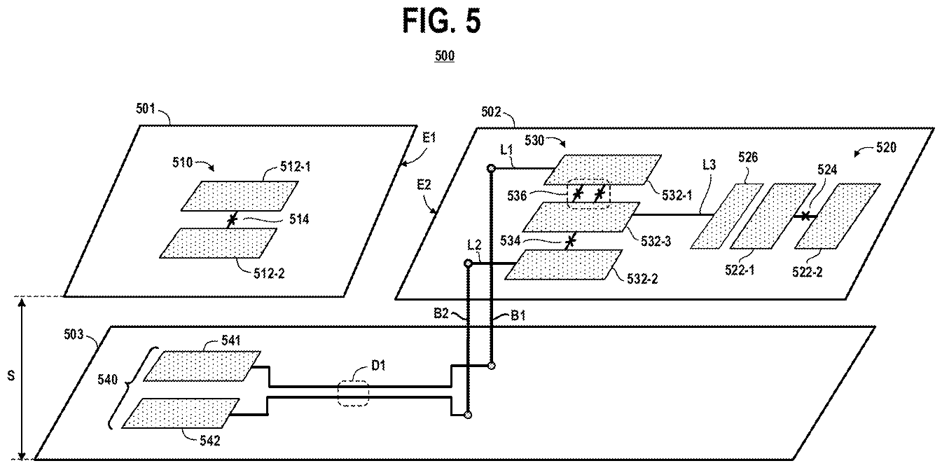

Next, FIG. 5 is a schematic perspective view of a package structure comprising qubit chips that are coupled using non-galvanic and differential coupling components, according to another exemplary embodiment of the disclosure. In particular, FIG. 5 schematically illustrates a package structure 500 comprising a first qubit chip 501, a second qubit chip 502, and a carrier substrate 503 (or interposer). The first and second qubit chips 501 and 502 have frontside surfaces with patterned metallization and circuitry which defines qubits, tunable couplers, transmission lines, etc. The first and second qubit chips 501 and 502 are flip-chip bonded via solder bump connections to a frontside surface of the carrier substrate 503, such that the first and second qubit chips 501 and 502 are (i) horizontally separated by a small gap between respective edges E1 and E2 of the first and second qubit chips 501 and 502, and (ii) vertically separated from the carrier substrate 503 by a vertical spacing S that defines a vacuum gap between the frontside surface of the carrier substrate 503 and the frontside surfaces of the first and second qubit chips 501 and 502. The vertical spacing S is fixed by the height of the bump connections post-bonding, wherein the vertical spacing S can be in a range of, e.g., 1 micron to 5 microns.

For example, FIG. 5 shows bump connections B1 and B2 (e.g., indium solder bump connections) between the second qubit chip 502 and the carrier substrate 503. However, for ease of illustration, FIG. 5 does not show ground planes on the first and second qubit chips 501 and 502 or the carrier substrate 503, or bump connections that would be used for, e.g., bonding the ground planes of the frontside surfaces of the first and second qubit chips 501 and 502 to the ground planes on the frontside surface of the carrier substrate 503, or used for making other direct (galvanic) connections between the carrier substrate 503 and other components on the first and second qubit chips 501 and 502.

The first qubit chip 501 comprises a first transmon qubit 510 which is formed on the frontside surface of the first qubit chip 501 and disposed in proximity to the edge E1 of the first qubit chip 501. In particular, FIG. 5 schematically shows an exemplary planar circuit configuration of the first transmon qubit 510 which comprises a first superconducting pad 512-1, a second superconducting pad 512-2, and a Josephson junction 514 that is coupled to, and disposed between, the first and second superconducting pads 512-1 and 512-2. The first and second superconducting pads 512-1 and 512-2 comprise first and second electrodes of a coplanar parallel-plate capacitor of the first transmon qubit 510, which is coupled in parallel with the Josephson junction 514.

The second qubit chip 502 comprises a second transmon qubit 520, and a tunable coupler 530, which are formed on the frontside surface of the second qubit chip 502 in proximity to the edge E2 of the second qubit chip 502. The second transmon qubit 520 comprises a first superconducting pad 522-1 and a second superconducting pad 522-2 (which form a parallel plate capacitor), and a Josephson junction 524 that is coupled to, and between, the first and second superconducting pads 522-1 and 522-2. Further, the tunable coupler 530 comprises a tunable multimode qubit coupler which comprises a first superconducting pad 532-1, a second superconducting pad 532-2, a third superconducting pad 532-3, a Josephson junction 534, and a SQUID 536 comprising two Josephson junctions. The Josephson junction 534 is coupled to, and disposed between, the second and third superconducting pads 532-2 and 332-3, and the SQUID 536 is coupled to, and disposed between, the first and third superconducting pads 532-1 and 332-3. As explained in further detail below, the tunable coupler 530 comprises a multimode qubit coupler architecture which is configured to have different operating modes, including a first mode and a second mode, which are used to mediate exchange couplings between the first and second transmon qubits 510 and 520.

The carrier substrate 503 comprises a differential coupling capacitor 540, and a pair of differential lines D1, which are formed on the frontside surface of the carrier substrate 503. The differential coupling capacitor 540 comprises a first capacitor pad 541 and a second capacitor pad 542. As schematically illustrated in FIG. 5, the first superconducting pad 512-1 of the first transmon qubit 510 is disposed over and aligned to the first capacitor pad 541 of the differential coupling capacitor 540, while the second superconducting pad 512-2 of the first transmon qubit 510 is disposed over and aligned to the second capacitor pad 542 of the differential coupling capacitor 540. In this configuration, the differential coupling capacitor 540 and the first and second superconducting pads 512-1 and 512-2 of the first transmon qubit 510 implement a vacuum gap capacitor structure which provides a non-galvanic connection between the first transmon qubit 510 (on the first qubit chip 501) and the carrier substrate 503.

The exemplary package structure 500 comprises a qubit-coupler-qubit system in which the tunable coupler 530 is capacitively coupled to both the first transmon qubit 510 and the second transmon qubit 520. In particular, the tunable coupler 530 is coupled to the first transmon qubit 510 using a differential coupling network which comprises first and second transmission lines L1 and L2 on the second qubit chip 502, the first and second bump connections B1 and B2, the pair of differential lines D1, and the first and second capacitor pads 541 and 542 of the differential coupling capacitor 540. In this configuration, the first superconducting pad 532-1 of the tunable coupler 530 is connected to the capacitor pad 541 by a series connection of the transmission line L1, the first bump connection B1, and one transmission line of the pair of differential lines D1, and the second superconducting pad 532-2 of the tunable coupler 530 is connected to the second capacitor pad 542 by a series connection of the transmission line L2, the second bump connection B2, and the other transmission line of the pair of differential lines D1.

In addition, the tunable coupler 530 is capacitively coupled to the second transmon qubit 520 by a coupling network which comprises a third transmission line L3 on the second qubit chip 502, and a capacitor pad 526. In particular, the capacitor pad 526 is connected to the third superconducting pad 532-3 of the tunable coupler 530 via the third transmission line L3. The capacitor pad 526 is disposed adjacent to an edge of the first superconducting pad 522-1 of the second transmon qubit 520 to implement a coplanar parallel plate capacitor to provide direct capacitive coupling (via gap capacitance) with a desired coupling capacitance Cc.

With the exemplary package structure 500, the transmission lines L1 and L2, the bump connections B1 and B2, the differential lines D1, and the differential coupling capacitor 540 collectively form a differential coupling network between the first transmon qubit 510 on the first qubit chip 501 and the tunable coupler 530 on the second qubit chip 502, wherein the differential coupling network serves to reduce or eliminate any adverse effects of external fields or other sources of noise, e.g., package modes between the first and second qubit chips 501 and 502, which can add noise to the common mode of exposed transmission lines. The differential coupling network configuration provides good immunity to such package modes and serves to significantly reduce or otherwise eliminate the coupling of package mode noise to the first and second transmon qubits 510 and 520.

In contrast to the package structure 300 of FIG. 3, the exemplary package structure 500 of FIG. 5 does not implement a second differential coupling network to capacitively couple the second transmon qubit 520 directly to the differential coupling capacitor 540. Instead, the tunable coupler 530 is configured as a multimode qubit coupler which has two sets of excitations, e.g., two different excitation modes including a first mode (bright mode mode) and a second mode (dark mode). When the tunable coupler 530 is tuned in an OFF state, the first transmon qubit 510 is coupled to the bright mode of the tunable coupler 530, and the second transmon qubit 520 is coupled to the dark mode of tunable coupler 530, which significantly suppresses or eliminates static/residual exchange interaction between the first and second transmon qubits 510 and 520 when the tunable coupler 530 is tuned in an OFF state.

Consequently, utilizing the tunable coupler 530 with different modes of excitation essentially eliminates the need to implement a second differential coupling network to achieve the differential cancellation of the small amount of residual/static exchange interaction between the first and second transmon qubits 510 and 520 when the tunable coupler 530 is tuned in an OFF state. In this configuration, the differential coupling capacitor 540 can be formed with two larger size capacitor pads 541 and 542, as compared to the differential coupling capacitor 340 in FIG. 3 which is formed with four smaller size capacitor pads. As such, the larger area of the capacitor pads 541 and 542 of the differential coupling capacitor 540 enables a stronger capacitive coupling to the first transmon qubit 510, which results in faster qubit gate speeds.

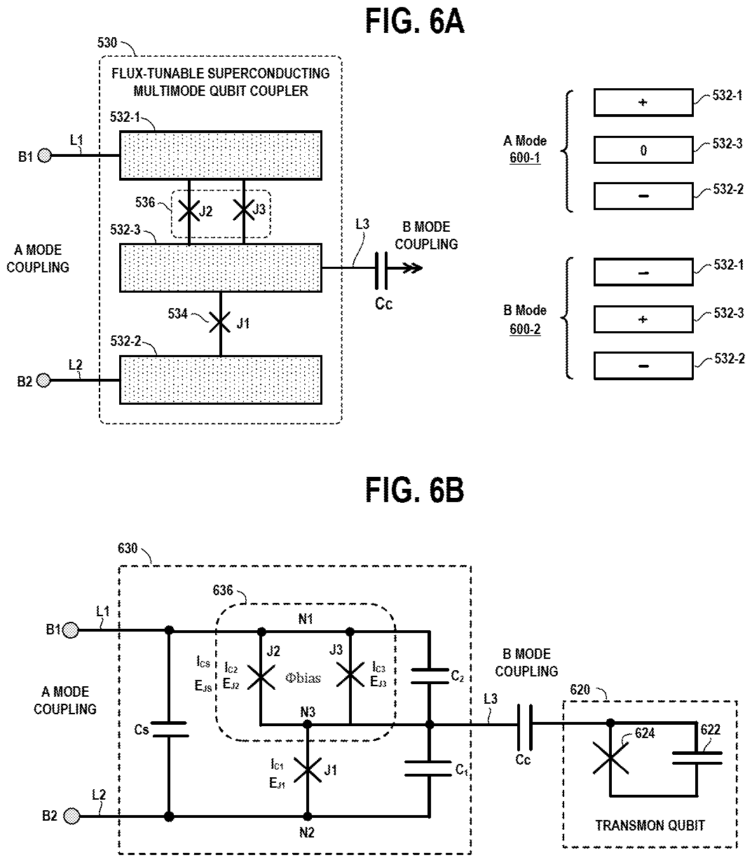

The exemplary architecture and associated modes of the tunable coupler 530 of FIG. 5 will now be discussed in further detail in conjunction with FIGS. 6A and 6B. For example, FIG. 6A schematically illustrates distinct modes of excitation of the tunable coupler 530 having a flux-tunable multimode qubit architecture, according to an exemplary embodiment of the disclosure. The tunable coupler 530 is alternatively referred to as a superconducting tunable coupler qubit (TCQ). As noted above, the exemplary planar configuration of the tunable coupler 530 comprises first, second, and third superconducting pads 532-1, 532-2, and 532-3, with the first Josephson junction 534 (J1) coupled to and between the second and third superconducting pads 532-2 and 532-3, and the SQUID 536 comprising two Josephson junctions J2 and J3 coupled to and between the first and third superconducting pads 532-1 and 532-3.

In general, the tunable coupler 530 with the tunable multimode qubit architecture comprises a combination of two strongly interacting, anharmonic oscillators with a composite quantum system characterized by multiple modes of excitations that exhibit strong longitudinal couplings amongst themselves, i.e., the excitation of one mode can strongly shift the transition frequency of another mode. In an exemplary embodiment, the tunable coupler 530 comprises two modes of excitations with distinct frequencies and distinct spatial symmetries. More specifically, the tunable coupler 530 comprises two distinct modes of excitation corresponding to symmetric and antisymmetric combinations of excitations associated with two capacitively-shunted Josephson junctions, wherein the two distinct, normal modes include (i) a low-frequency “bright” mode (referred to herein as A mode) which comprises a non-zero dipole moment, and (ii) a high-frequency “dark” mode (referred to herein as B mode) which lacks a dipole moment and does not couple to external fields.

FIG. 6A schematically illustrates the two distinct modes of excitations of the tunable coupler 530 in which the “bright” mode is depicted as an A mode 600-1, and the “dark” mode is depicted as a B mode 600-2. The A mode 600-1 comprises a charge pattern in which, at any given point in time, the first and second superconducting pads 532-1 and 532-2 have opposite charges, and the third superconducting pad 532-3 has a net zero charge. On the other hand, the B mode 600-2 comprises a charge pattern in which, at any given point in time, the first and second superconducting pads 532-1 and 532-2 have the same charge, and the third superconducting pad 532-3 has a charge that is opposite the charge on the first and second superconducting pads 532-1 and 532-2. The A and B modes have different frequencies, e.g., a mode frequency f_{B} of the B mode 600-2 is greater than a mode frequency f_{A} of the A mode 600-1, which allows individual excitation of one mode over the other mode.

FIG. 6B illustrates a schematic lumped-element circuit representation of a tunable coupler (e.g., tunable coupler 530) comprising a flux-tunable multimode qubit architecture, according to an exemplary embodiment of the disclosure. In particular, FIG. 6B schematically illustrates a flux-tunable multimode qubit 630 having a flux-tunable multimode, two-junction superconducting qubit architecture, which comprises a shunt capacitor C_{S} coupled to first and second nodes N1 and N2, and two capacitively-shunted superconducting Josephson junctions connected in series to and between the first node N1 and the second node N2 of the flux-tunable multimode qubit 630.

More specifically, a first capacitively-shunted Josephson junction comprises a Josephson junction J1 connected in parallel with a first capacitor C₁ between the second node N2 and a third node N3. The Josephson junction J1 comprises a critical current I_{C1} and a Josephson energy E_{J1}. Further, a second capacitively-shunted Josephson junction comprises a SQUID 636 connected in parallel with a second capacitor C₂. The SQUID 636 comprises two Josephson junctions J2 and J3 which are connected in parallel between the first node N1 and the third node N3 of the flux-tunable multimode qubit 630 to form a superconducting loop. The Josephson junction J2 comprises a critical current I_{C2} and a Josephson energy E_{J2}. The Josephson junction J3 comprises a critical current IC₃ and a Josephson energy E3.

It is to be noted that in the exemplary schematic lumped-element circuit representation of the flux-tunable multimode qubit 630 in FIG. 6B, the nodes N1, N2, and N3 correspond to the first, second, and third superconducting pads 532-1, 532-2, and 532-3 of the tunable coupler 530 shown in FIG. 6A. In addition, the first, second, and third superconducting pads 532-1, 532-2, and 532-3 of the tunable coupler 530 shown in FIG. 6A comprise planar capacitor electrodes which form coplanar parallel-plate capacitor structures that correspond to the capacitors C_{S}, C₁, and C₂ shown in FIG. 6B. In particular, the first and second superconducting pads 532-1 and 532-2 comprise a coplanar parallel-plate capacitor structure which corresponds to the shunt capacitor C_{S}. The second and third superconducting pads 532-3 and 532-3 comprise a coplanar parallel-plate capacitor structure which corresponds to the shunt capacitor C₁. The first and third superconducting pads 532-1 and 532-3 comprise a coplanar parallel-plate capacitor structure which corresponds to the shunt capacitor C₂.

The SQUID 636 effectively operates as a single Josephson junction with an effective critical current I_{CS} and Josephson energy E_{JS}, based on the critical currents I_{C2} and I_{C3} and Josephson energies E_{J2} and E_{J3} of the respective Josephson junctions J2 and J3 of the SQUID 636. The effective critical current I_{CS} and Josephson energy E_{JS} of the SQUID 636 can be adjusted by threading an external magnetic flux bias Φ_{Bias} through the superconducting SQUID loop formed by the Josephson junctions J2 and J3 to change an operating mode of the flux-tunable multimode qubit 630. The external magnetic flux bias Φ_{Bias} modulates the critical current I_{CS}, and thus, the Josephson energy E_{JS} of the SQUID 636 in a very specific manner.

When utilized as a flux-tunable coupler, the operating mode of the flux-tunable multimode qubit 630 can be tuned to control the exchange interaction (e.g., facilitate exchange interaction or suppress crosstalk) between first and second superconducting qubits that are capacitively coupled to the A mode and B mode, respectively, of the flux-tunable multimode qubit 630. For example, in the context of the exemplary embodiment of the package structure 500 of FIG. 5 where the tunable coupler 530 is implemented using the flux-tunable multimode qubit 630 of FIG. 6B, the first node N1 of the flux-tunable multimode qubit 630 is connected to the first bump connection B1 via the first transmission line L1, and the second node N2 is connected to the second bump connection B2 via the second transmission line L2, thereby coupling the first transmon qubit 510 to the A mode of the flux-tunable multimode qubit 630.

In addition, the third node N3 of the flux-tunable multimode qubit 630 is connected to the coupling capacitor pad 526 via the third transmission line L3, which results in capacitive coupling of the second transmon qubit 520 to the B mode of the flux-tunable multimode qubit 630. It is to be noted that in FIG. 6B, the second transmon qubit 520 of FIG. 5 is schematically shown as a lumped-element circuit representation of a transmon qubit 620 comprising a capacitor 622 and Josephson junction 624. In FIG. 6B, a coupling capacitor Cc represents a capacitive coupling (via gap capacitance) between the coupling capacitor pad 526 and the superconducting pad 522-1 of the second transmon qubit 520.

The flux-tunable multimode qubit 630 can be tuned to operate in a first state (e.g., “OFF” state or “deactivated” state) or a second state (e.g., “ON” state or “activated” state) by changing an amount of external magnetic flux bias Φ_{Bias} threaded through the superconducting loop of the SQUID 636 to adjust the critical current I_{CS} and, thus, adjust the Josephson energy E_{JS} of the SQUID 636. For example, the flux-tunable multimode qubit 630 can be tuned to operate in a “OFF” state by applying an amount of external magnetic flux bias Φ_{Bias} to the superconducting loop of the SQUID 636 to make the critical current I_{CS} of the SQUID 636 to be equal to, or substantially equal to, the critical current I_{C1} of the Josephson junction J1, which causes a balance in the respective Josephson energies E_{J1} and E_{JS} of the Josephson junction J1 and the SQUID 636.

In the “OFF” state, the flux-tunable multimode qubit 630 enforces a mode-selective coupling and creates a condition of essentially zero interaction between first and second superconducting qubits that are capacitively coupled to the respective A and B modes. More specifically, in the “OFF” state of the flux-tunable multimode qubit 630, the first superconducting qubit which is capacitively coupled to the nodes N1 and N2 of the flux-tunable multimode qubit 630 is exchange coupled to only the A mode of the flux-tunable multimode qubit 630, and the superconducting qubit which is capacitively coupled to the node N3 of the flux-tunable multimode qubit 630 is exchange coupled to only the B mode of the flux-tunable multimode qubit 630. In the “OFF” state of the flux-tunable multimode qubit 630, the A and B modes have distinct and separate charge patterns such as shown in FIG. 6A, which results in suppressing crosstalk (e.g., static ZZ interaction) between the first and second superconducting qubits that are coupled by the flux-tunable multimode qubit 630.

On the other hand, the flux-tunable multimode qubit 630 can be tuned to operate in an “ON” state by applying an amount of external magnetic flux bias Φ_{Bias} to the superconducting loop of the SQUID 636 to make the critical current I_{CS} of the SQUID 636 unequal to (e.g., greater than) the critical current I_{C1} of the Josephson junction J1, which causes an imbalance in the respective Josephson energies E_{J1} and E_{JS} of the Josephson junction J1 and the SQUID 636. The imbalance in the Josephson energies E_{J1} and E_{JS} modifies the distinct charge patterns of the A and B modes in such a way as to cause the charge patterns to become linear combinations of the distinct charge patterns shown in FIG. 6A, which disrupts the mode-selective coupling of the flux-tunable multimode qubit 630, and causes the first and second superconducting qubits to have exchange coupling to both the A mode and the B mode of flux-tunable multimode qubit 630. In the “ON” state of the flux-tunable multimode qubit 630, exchange coupling of both the first and second superconducting qubits to both the A mode and the B mode results in exchange coupling (e.g., ZZ interaction) between the first and second superconducting qubits that are capacitively coupled to the A and B modes of the flux-tunable multimode qubit 630.

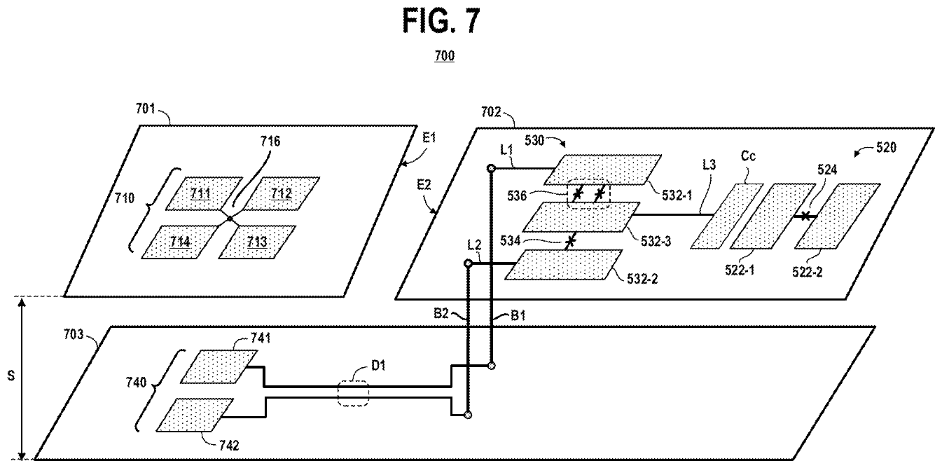

Next, FIG. 7 is a schematic perspective view of a package structure comprising qubit chips that are coupled using non-galvanic and differential coupling components, according to another exemplary embodiment of the disclosure. In particular, FIG. 7 schematically illustrates a package structure 700 comprising a first qubit chip 701, a second qubit chip 702, and a carrier substrate 703 (or interposer), wherein the first and second qubit chips 701 and 702 are flip-chip bonded to the carrier substrate 703 using bump connections (e.g., bump connections B1 and B2). In the exemplary embodiment, the first qubit chip 701 comprises a superconducting quadrupole transmon qubit 710 which comprises a plurality of superconducting pads 711, 712, 713, and 714, and a Josephson junction 716 having a Manhattan Josephson junction framework. The exemplary architecture and operation of the superconducting quadrupole transmon qubit 710 is the same as the superconducting quadrupole transmon qubit 410 shown in FIG. 4, the details of which will not be repeated. In addition, the second qubit chip 702 comprises the same circuit architecture (e.g., second transmon qubit 520 and tunable coupler 530) as the second qubit chip 502 shown FIGS. 5, 6A, and 6B, the details of which will not be repeated.

In addition, the carrier substrate 703 is similar to the carrier substrate 503 of FIG. 5 as discussed above, except that the carrier substrate 703 comprises a differential coupling capacitor 740 which comprises a first capacitor pad 741 and a second capacitor pad 742 that are structurally configured and arranged to capacitively couple to the superconducting quadrupole transmon qubit 710 to implement a vacuum gap capacitor structure which provides a non-galvanic connection between the superconducting quadrupole transmon qubit 710 and the carrier substrate 703. For example, the superconducting pad 712 of the superconducting quadrupole transmon qubit 710 is disposed over and aligned to the first capacitor pad 741 of the differential coupling capacitor 740, and the superconducting pad 713 of the superconducting quadrupole transmon qubit 710 is disposed over and aligned to the second capacitor pad 742 of the differential coupling capacitor 740. With this configuration, the first capacitor pad 741 of the differential coupling capacitor 740 is capacitively coupled to a first capacitor electrode comprising the superconducting pads 712 and 714 of the superconducting quadrupole transmon qubit 710, and the second capacitor pad 742 of the differential coupling capacitor 740 is capacitively coupled to a second capacitor electrode comprising the superconducting pads 711 and 713 of the superconducting quadrupole transmon qubit 710.

In the package structure 700 of FIG. 7, the implementation of the tunable coupler 530 comprising a multimode qubit coupler architecture enables the use the single pair of differential lines D1 for purposes reducing coupling to stray fields or modes that might exist between the first and second qubit chips 701 and 702. Indeed, the implementation of the differential coupling network comprising the differential lines D1 and the differential coupling capacitor 740 serves to reduce or eliminate any adverse effects of external fields or other sources of noise, e.g., package modes between the first and second qubit chips 501 and 502, which can add noise to the common mode of exposed transmission lines. In addition, as noted above, the implementation of the superconducting quadrupole transmon qubit 710 on the first chip serves to reduce the coupling to stray fields or modes that might exist between the first and second qubit chips 701 and 702.

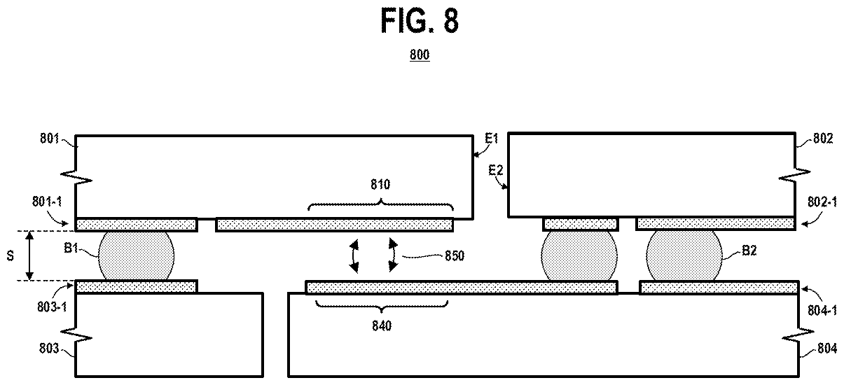

In other embodiments of the disclosure, multi-qubit chip package structures are constructed using multiple qubit chips mounted on separate carrier substrates, wherein non-galvanic and differential coupling is implemented between a qubit chip on one carrier substrate and another qubit chip on another substrate. For example, FIG. 8 is a schematic cross-sectional side view of a package structure comprising qubit chips that are coupled using non-galvanic and differential coupling components, according to another exemplary embodiment of the disclosure. In particular, FIG. 8 schematically illustrates a package structure 800 comprising a first qubit chip 801, a second qubit chip 802, a first carrier substrate 803, and a second carrier substrate 804. The first qubit chip 801 is flip-chip bonded to the first carrier substrate 803 using bump connections (e.g., bump connection B1), and the second qubit chip 802 is flip-chip bonded to the second carrier substrate 804 using bump connections (e.g., bump connection B2.) The first quantum bit chip 801 is mounted on the first carrier substrate 803 such that an extended portion of the first quantum bit chip 801 extends past an edge of the first carrier substrate 803 and overlaps a region of the second carrier substrate 804.

The first qubit chip 801 comprises a frontside surface 801-1 having patterned metallization and circuitry which defines qubits, tunable couplers, transmission lines, bond pads, etc. Similarly, the second qubit chip 802 comprises a frontside surface 802-1 having patterned metallization and circuitry which defines qubits, tunable couplers, transmission lines, bond pads, ground planes, etc. The first carrier substrate 803 comprises a frontside surface 803-1 having patterned metallization which defines, e.g., an inter-chip coupling network (e.g., differential capacitors, differential transmission lines), ground planes, bond pads, etc. Similarly, the second carrier substrate 804 comprises a frontside surface 804-1 having patterned metallization which defines, e.g., an inter-chip coupling network (e.g., differential capacitors, differential transmission lines), ground planes, bond pads, etc.

As noted above, the first qubit chip 801 is flip-chip mounted to the first carrier substrate 803 such that an end portion (with edge E1) of the first qubit chip 801 extends past an edge of the first carrier substrate 803 and overlaps an end region of the second carrier substrate 804. The extended portion of the first qubit chip 801 comprises patterned metallization and other components that implement a first qubit 810, wherein the first qubit 810 is disposed over and aligned to, e.g., a differential capacitor 840 which is disposed in the overlapped region of the frontside surface 804-1 of the second carrier substrate 804. This exemplary overlapping configuration enables a non-galvanic and differential coupling (schematically illustrated by curved arrows 850) between the first and second qubit chips 801 and 802 on neighboring carrier substrates (e.g., first and second carrier substrates 803 and 804).

It is to be noted that the exemplary package structures shown in FIGS. 3, 4, 5, and 7 can be implemented with overlapping configurations, such as shown in FIG. 8, with the assumption that the first qubit chips 301, 401, 501, and 701 as shown in FIGS. 3, 4, 5, and 7, respectively, are flip-chip bonded to separate carrier substrates, and wherein FIGS. 3, 4, 5, and 7 schematically illustrate portions of the first qubit chips 301, 401, 501, and 701 which overlap (but are not bonded to) the carrier substrates 303, 403, 503, and 703, respectively. The exemplary overlapping configuration shown in FIG. 8 provides an advantage of allowing two separate qubit chips to be mounted on separate carrier substrates (or interposers) while allowing non-galvanic coupling between the two separate qubit chips.

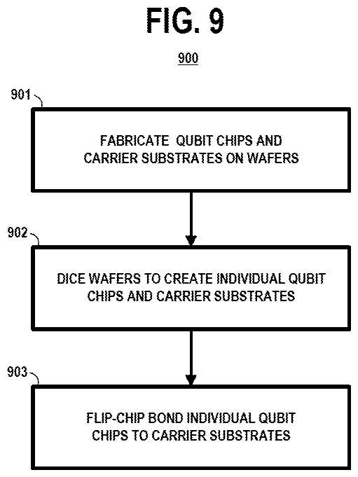

The exemplary package structures (e.g., multi-qubit chip package structure) discussed herein can be fabricated using state of the art semiconductor fabrication technologies. FIG. 9 illustrates a flow diagram of a process 900 for fabricating a multi-qubit package structure comprising qubit chips that are coupled using non-galvanic and differential coupling components, according to an exemplary embodiment of the disclosure. A plurality of qubit chips and carrier substrates are fabricated on wafers (e.g., qubit wafers and carrier substrate wafers) comprising suitable wafer material, e.g., high-resistivity silicon substrates (block 901). For example, on a given qubit wafer, various components of the qubits including the superconducting pads of qubits and tunable couplers, ground planes, signal coplanar waveguides, coupler drive lines, qubit drive lines, readout resonators, coupling capacitor pads, coupling inductors, solder bump bond pads, etc., comprise lithographically defined patterns of superconducting materials formed on the qubit wafer, which are formed using by, e.g., deposition, optical lithography, etch, and liftoff steps. In addition, on a given carrier substrate wafer, various components for implementing differential coupling networks (e.g., differential coupling capacitors, differential lines), ground planes, solder bump bond pads, and package I/O routing and interconnect transmission lines and bond pads, etc., comprise lithographically defined patterns of superconducting materials formed on the qubit wafer, which are formed using by, e.g., deposition, optical lithography, etch, and liftoff steps.

The circuit components on the qubit chip and carrier substrate wafers can be formed using various types of superconductor materials that are suitable for a given application, including, but not limited to, elementary metals such as niobium (Nb), aluminum (Al), tantalum (Ta), and compounds such as titanium nitride (TiN), niobium nitride (NbN), niobium titanium nitride (NbTiN), etc. The Josephson junctions may comprise an Al—AlOₓ—Al trilayer tunnel junctions that are fabricated using electron beam lithography with double-angle evaporation of aluminum with in-situ oxidation to form tunnel barriers, or other suitable fabrication techniques.

The qubit wafer is then diced to create individual qubit chips (or individual qubit dies) (block 902). In some embodiments, the carrier substrate wafer is diced to create individual carrier substrates. A plurality of the qubit chips are then flip-chip bonded to each carrier substrate (block 903). In some embodiments, flip-chip bonding of the qubit chips to the carrier substrates is performed by depositing and patterning indium solder bumps onto the carrier substrate. The qubit chips are then flipped and properly aligned to the carrier substrate, and a thermo-compression bonding process is performed to create galvanic connections between the qubit chips and the carrier saturates (e.g., the exemplary bump connections B1, B2, B3, and B4 shown in the exemplary package structures of FIGS. 3, 4, 5, 7, and 8), while ensuring that the differential coupling capacitors on the carrier substrate and superconducting pads of qubits on the qubit chips are properly aligned and vertically spaced to implement the vacuum gap capacitor configurations for the non-galvanic connections between the qubit chips and carrier substrate.

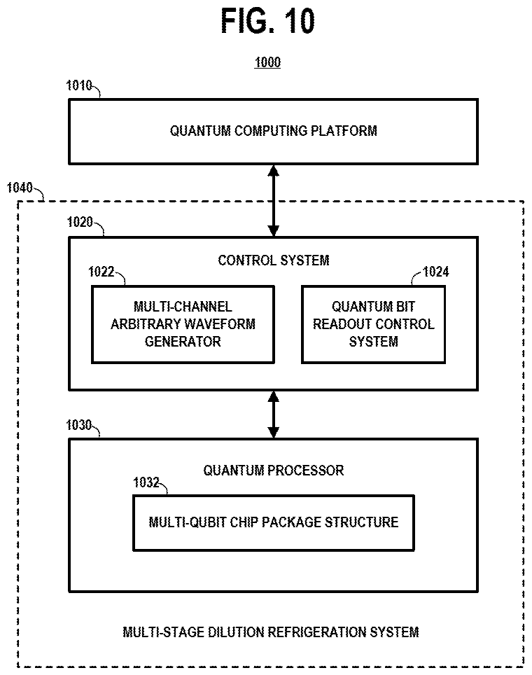

FIG. 10 schematically illustrates a quantum computing system which can be implemented using a multi-qubit chip package structure, according to an exemplary embodiment of the disclosure. In particular, FIG. 10 schematically illustrates a quantum computing system 1000 which comprises a quantum computing platform 1010, a control system 1020, and a quantum processor 1030. In some embodiments, the control system 1020 comprises a multi-channel arbitrary waveform generator 1022, and a quantum bit readout control system 1024. In an exemplary embodiment, the quantum processor 1030 comprises at least one multi-qubit chip package structure 1032 which comprises a plurality of qubit chips that are flip-chip bonded to a carrier substrate, wherein inter-chip coupling of the qubits chips is implemented using non-galvanic and differential coupling components. For example, the multi-qubit chip package structure 1032 can be implemented using any one of the exemplary package structures shown in FIGS. 3, 4, 5, 7, and 8, as may be needed for a given application or quantum system configuration.

In some embodiments, the control system 1020 and the quantum processor 1030 are disposed in a dilution refrigeration system 1040 which can generate cryogenic temperatures that are sufficient to operate components of the control system 1020 for quantum computing applications. For example, the quantum processor 1030 may need to be cooled down to near-absolute zero, e.g., 10-15 millikelvin (mK), to allow the superconducting qubits to exhibit quantum behaviors. In some embodiments, the dilution refrigeration system 1040 comprises a multi-stage dilution refrigerator where the components of the control system 1020 can be maintained at different cryogenic temperatures, as needed. For example, while the quantum processor 1030 may need to be cooled down to, e.g., 10-15 mK, the circuit components of the control system 1020 may be operated at cryogenic temperatures greater than 10-15 mK, depending on the configuration of the quantum computing system. In other embodiments, some or all of the components of the control system 1020 may comprise electronic components that are disposed and operated in room temperature environment.

In some embodiments, the multi-channel arbitrary waveform generator (AWG) 1022 and other suitable microwave pulse signal generators are configured to generate the microwave control pulses that are applied to the qubit drive lines, and the coupler drive lines to control the operation of the superconducting qubits and associated qubit coupler circuitry, when performing various gate operations to execute a given certain quantum information processing algorithm. In some embodiments, the multi-channel AWG 1022 comprises a plurality of AWG channels, which control respective superconducting qubits on qubit chips within the multi-qubit chip package structure 1032 of the quantum processor 1030. In some embodiments, each AWG channel comprises a baseband signal generator, a digital-to-analog converter (DAC) stage, a filter stage, a modulation stage, and an impedance matching network, and a phase-locked loop system to generate local oscillator (LO) signals (e.g., quadrature LO signals LO_I and LO_Q) for the respective modulation stages of the respective AWG channels.

In some embodiments, the multi-channel AWG 1022 comprises a quadrature AWG system which is configured to process quadrature signals, wherein a quadrature signal comprises an in-phase (I) signal component, and a quadrature-phase (Q) signal component. In each AWG channel the baseband signal generator is configured to receive baseband data as input (e.g., from the quantum computing platform), and generate digital quadrature signals I and Q which represent the input baseband data. In this process, the baseband data that is input to the baseband signal generator for a given AWG channel is separated into two orthogonal digital components including an in-phase (I) baseband component and a quadrature-phase (Q) baseband component. The baseband signal generator for the given AWG channel will generate the requisite digital quadrature baseband IQ signals which are needed to generate an analog waveform (e.g., sinusoidal voltage waveform) with a target center frequency that is configured to operate or otherwise control a given quantum bit that is coupled to the output of the given AWG channel.

The DAC stage for the given AWG channel is configured to convert a digital baseband signal (e.g., a digital IQ signal output from the baseband signal generator) to an analog baseband signal (e.g., analog baseband signals I(t) and Q(t)) having a baseband frequency. The filter stage for the given AWG channel is configured to the filter the IQ analog signal components output from the DAC stage to thereby generate filtered analog IQ signals. The modulation stage for the given AWG channel is configured to perform analog IQ signal modulation (e.g., single-sideband (SSB) modulation) by mixing the filtered analog signals I(t) and Q(t), which are output from the filter stage, with quadrature LO signals (e.g., an in-phase LO signal (LO_I) and a quadrature-phase LO signal (LO_Q)) to generate and output an analog RF signal (e.g., a single-sideband modulated RF output signal).

In some embodiments, the quantum bit readout control system 1024 comprises a microwave pulse signal generator that is configured to applying a microwave tone to a given readout resonator line of a given superconducting qubit to perform a readout operation to readout the state of the given superconducting qubit, as well as circuitry that is configured to process the readout signal generated by the readout resonator line to determine the state of the given superconducting qubit, using techniques known to those of ordinary skill in the art. For example, in some embodiments, as noted above, a qubit readout line for a given qubit comprise a coplanar waveguide resonator that is configured to have a resonant frequency that is detuned from a transition frequency of the given qubit to enable a dispersive readout operation for reading the quantum state of a given qubit which is coupled to a given readout resonator. Furthermore, as noted above, a dispersive readout operation involves applying an RF readout control signal (RF_RO) to the given readout resonator, and detecting/processing the readout signal that is reflected out from the given readout resonator. An RF readout control signal that is applied to the given readout resonator has a single frequency tone that is the same or similar to the resonant frequency of the readout resonator, a pulse envelope with a given pulse shape (e.g., gaussian pulse envelope), and given pulse duration. In the dispersive regime of qubit-resonator coupling, the RF readout control signal interacts with the given qubit/resonator system, and the resulting output readout signal which is reflected out from the given readout resonator comprises information (e.g., phase and/or amplitude) that is qubit-state dependent.

The quantum computing platform 1010 comprises a software and hardware platform which comprises various software layers that are configured to perform various functions, including, but not limited to, generating and implementing various quantum applications using suitable quantum programming languages, configuring and implementing various quantum gate operations, compiling quantum programs into a quantum assembly language, implementing and utilizing a suitable quantum instruction set architecture (ISA), etc. In addition, the quantum computing platform 1010 comprises a hardware architecture of processors, memory, etc., which is configured to control the execution of quantum applications, and interface with the control system 1020 to (i) generate digital control signals that are converted to analog microwave control signals by the control system 1020, to control operations of the quantum processor 1030 when executing a given quantum application, and (ii) to obtain and process digital signals received from the control system 1020, which represent the processing results generated by the quantum processor 1030 when executing various gate operations for a given quantum application.

In some exemplary embodiments, the quantum computing platform 1010 of the quantum computing system 1000 may be implemented using any suitable computing system architecture which is configured to implement methods to support quantum computing operations by executing computer readable program instructions that are embodied on a computer program product which includes a computer readable storage medium (or media) having such computer readable program instructions thereon for causing a processor to perform control methods as discussed herein.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A package structure, comprising:
a first quantum bit chip and a second quantum bit chip mounted on a carrier substrate; and
an inter-chip coupling network disposed on the carrier substrate, and configured to provide non-galvanic and differential coupling of the first quantum bit chip and the second quantum bit chip.

2. The package structure of claim 1, wherein the inter-chip coupling network comprises:
a differential coupling capacitor; and
a first pair of differential transmission lines connected to the differential coupling capacitor.

3. The package structure of claim 2, wherein:
the differential coupling capacitor is aligned to superconducting pads of a first quantum bit on the first quantum bit chip to implement a vacuum gap capacitor which provides a non-galvanic connection; and
the first pair of differential lines are coupled to a tunable coupler on the second quantum bit chip.

4. The package structure of claim 3, wherein the first pair of differential lines are galvanically coupled to the tunable coupler via solder bump connections between the second quantum bit chip and the carrier substrate.

5. The package structure of claim 3, wherein:
the inter-chip coupling network further comprises a second pair of differential transmission lines connected to the differential coupling capacitor; and
the second pair of differential transmission lines are coupled to a second quantum bit on the second quantum bit chip.

6. The package structure of claim 5, wherein the second quantum bit is capacitively and differentially coupled to the tunable coupler.

7. A package structure, comprising:
a first quantum bit chip and a second quantum bit chip, which are mounted on a carrier substrate;
the first quantum bit chip comprising a first quantum bit;
the second quantum bit chip comprising a second quantum bit, and a tunable coupler that is configured to control exchange interactions between the first quantum bit and the second quantum bit; and
the carrier substrate comprising an inter-chip coupling network which is configured to provide non-galvanic and differential coupling of the tunable coupler and the first quantum bit chip.

8. The package structure of claim 7, wherein the inter-chip coupling network is further configured to provide non-galvanic and differential coupling of the first quantum bit and the second quantum bit.

9. The package structure of claim 7, wherein the inter-chip coupling network comprises:
a differential coupling capacitor comprising capacitor pads aligned to respective superconducting pads of the first quantum bit on the first quantum bit chip; and
a pair of differential transmission lines connected to the differential coupling capacitor;
wherein the pair of differential transmission lines is coupled to the tunable coupler on the second quantum bit chip via galvanic connections between the carrier substrate and the second quantum bit chip.

10. The package structure of claim 9, wherein:
the differential coupling capacitor comprises a first capacitor pad and a second capacitor pad;
the first quantum bit comprises a first superconducting pad and a second superconducting pad;
the first quantum bit chip is mounted on the carrier substrate with the first superconducting pad and the second superconducting pad of the first quantum bit disposed in alignment with the first capacitor pad and the second capacitor pad, respectively, of the differential coupling capacitor on the carrier substrate.

11. The package structure of claim 9, wherein:
the differential coupling capacitor comprises a first capacitor pad and a second capacitor pad;
the first quantum bit comprises a quadrupole transmon quantum bit comprising a first superconducting pad, a second superconducting pad, a third superconducting pad, and a fourth superconducting pad;
the first quantum bit chip is mounted on the carrier substrate with the first superconducting pad and the second superconducting pad of the quadrupole transmon quantum bit disposed in alignment with the first capacitor pad and the second capacitor pad, respectively, of the differential coupling capacitor on the carrier substrate.

12. The package structure of claim 7, wherein the inter-chip coupling network comprises:
a differential coupling capacitor comprising a first capacitor pad, a second capacitor pad, a third capacitor pad, and a fourth capacitor pad;
a first pair of differential transmission lines connected to the first and second capacitor pads of the differential coupling capacitor; and
a second pair of differential transmission lines connected to the third and fourth capacitor pads of the differential coupling capacitor;
wherein the first pair of differential transmission lines is coupled to the tunable coupler on the second quantum bit chip via a first set of galvanic connections between the carrier substrate and the second quantum bit chip; and
wherein the second pair of differential transmission lines is coupled to the second quantum bit via a second set of galvanic connections between the carrier substrate and the second quantum bit chip.

13. The package structure of claim 12, wherein:
the first quantum bit comprises a quadrupole transmon quantum bit comprising a first superconducting pad, a second superconducting pad, a third superconducting pad, and a fourth superconducting pad;
the first quantum bit chip is mounted on the carrier substrate with the first, second, third, and fourth superconducting pads of the quadrupole transmon quantum bit disposed in alignment with the first, second, third, and fourth capacitor pads, respectively, of the differential coupling capacitor on the carrier substrate.

14. The package structure of claim 12, wherein:
the first quantum bit comprises a transmon quantum bit comprising a first superconducting pad and a second superconducting pad; and
the first quantum bit chip is mounted on the carrier substrate with (i) the first superconducting pad of the transmon quantum bit disposed in alignment with the both the first and fourth capacitor pads of the differential coupling capacitor, and (ii) the second superconducting pad of the transmon quantum bit disposed in alignment with the both the second and third capacitor pads of the differential coupling capacitor.

15. The package structure of claim 7, wherein the first quantum bit and the second quantum bit each comprise a transmon quantum bit, and the tunable coupler comprises a flux-tunable transmon quantum bit.

16. The package structure of claim 7, wherein the first quantum bit comprises a quadrupole transmon quantum bit.

17. The package structure of claim 7, wherein:
the tunable coupler comprises a flux-tunable multimode quantum bit;
the flux-tunable multimode quantum bit comprises a first mode and a second mode, and is configured to operate in one of a first state and a second state, in response to a flux tuning control signal applied thereto;
wherein in the first state of the flux-tunable multimode quantum bit, the first quantum bit is exchange coupled to the first mode, and the second quantum bit is exchange coupled to the second mode, to suppress interaction between the first quantum bit and the second quantum bit; and
wherein in the second state of the flux-tunable multimode quantum bit, the first quantum bit and the second quantum bit are exchange coupled to both the first mode and the second mode, to enable interaction between the first quantum bit and the second quantum bit.

18. A package structure, comprising:
a first quantum bit chip mounted on a first carrier substrate;
a second quantum bit chip mounted on a second carrier substrate, wherein an extended portion of the second quantum bit chip extends past an edge of the second carrier substrate and overlaps a region of the first carrier substrate; and
an inter-chip coupling network disposed at least in part in the overlapped region of the first carrier substrate, and configured to provide non-galvanic and differential coupling of the first quantum bit chip and the second quantum bit chip.

19. The package structure of claim 18, wherein the inter-chip coupling network comprises:
a differential coupling capacitor; and
a pair of differential transmission lines connected to the differential coupling capacitor.

20. The package structure of claim 19, wherein:
the differential coupling capacitor is aligned to superconducting pads of a quantum bit disposed in the extended portion of the second quantum bit chip to implement a vacuum gap capacitor which provides a non-galvanic connection; and
the pair of differential lines are coupled to a tunable coupler on the first quantum bit chip.
